(19) United States
(12) Patent Application Publication
(10) Pub. No.: US 2026/0314126 A1
(43) Pub. Date: Oct. 8, 2026

(54) PHOSPHOR, LIGHT EMITTING DEVICE, LIGHTING DEVICE, IMAGE DISPLAY DEVICE, AND INDICATOR LAMP FOR VEHICLES

(71) Applicants: National Institute for Materials Science, Ibaraki (JP); Mitsubishi Chemical Corporation, Tokyo (JP)

(72) Inventors: Kyota Ueda, Tokyo (JP); Tomoyuki Kurushima, Tokyo (JP); Atsushi Ooishi, Tokyo (JP); Naoto Hirosaki, Ibaraki (JP)

(73) Assignees: National Institute for Materials Science, Ibaraki (JP); Mitsubishi Chemical Corporation, Tokyo (JP)

(21) Appl. No.: 19/678,478

(22) Filed: May 15, 2026

Related U.S. Application Data
(63) Continuation of application No. PCT/JP2024/040712, filed on Nov. 15, 2024.

(30) Foreign Application Priority Data
Nov. 15, 2023 (JP) 2023-194412

(51) Int. Cl. H10H 20/851; C09K 11/77

(52) U.S. Cl. CPC H10H 20/8512; C09K 11/7787; C09K 11/7791; C09K 11/77926

(57) ABSTRACT

A phosphor includes a crystal phase having a composition represented by Formula [1] MA_{a-x-y-z}ReₓMY_{y}MZ_{z}MB_{b}MC_{3-w}MW_{w}D_{d} or Formula [2] MA_{a-x-y}ReₓMY_{y}MB_{b+v1}MC₃₋ᵥ₂D_{d} (where the definition of each symbol is as described in the specification). A light-emitting device includes the phosphor. A lighting device includes the light-emitting device. An image display includes the light-emitting device. A vehicle indicator lamp includes the light-emitting device.

### CROSS-REFERENCE TO RELATED APPLICATIONS

This application is a continuation of International Application No. PCT/JP2024/040712, filed on Nov. 15, 2024, and claims the benefit of priority to Japanese Application No. 2023-194412 filed on Nov. 15, 2023. The content of each of these applications is hereby incorporated by reference in its entirety.

### TECHNICAL FIELD

The present invention relates to a phosphor, a light-emitting device, a lighting device, an image display device, and a vehicle indicator lamp.

### BACKGROUND ART

In recent years, in response to the trend of energy conservation, demand for lighting or a backlight using an LED has increased. The LED used here is a white light-emitting LED in which a phosphor is disposed on an LED chip that emits light of a blue or near-ultraviolet wavelength.

As such a type of white light-emitting LED, a white light-emitting LED, which uses a nitride phosphor that emits red light and a phosphor that emits green light on a blue LED chip, using blue light from the blue LED chip as excitation light, is used in recent years. Further light emission efficiency is required for LED. Also, a phosphor having excellent light emission characteristics is required for the red phosphor and a light-emitting device including such a phosphor is desired.

As the red phosphor used in the light-emitting device, for example, a KSF phosphor represented by the general formula K₂(Si,Ti)F₆:Mn, or K₂Si₁₋ₓNaₓAlₓF₆:Mn (0<x<1), an S/CASN phosphor represented by the general formula (Sr,Ca)AlSiN₃:Eu are known. However, the KSF phosphor is a deleterious substance activated by Mn, and thus, a phosphor that is more friendly to the human body and the environment is required. In addition, many of the S/CASN phosphor has a relatively wide full width at half maximum (hereinafter, sometimes referred to as “spectrum full width at half maximum”, “a full width at half maximum” or “FWHM”) in the emission spectrum, of about 80 nm to 90 nm, and the emission wavelength region tends to include a wavelength region with low relative luminosity. Thus, from the viewpoint of improving the conversion efficiency, a red phosphor having a narrow spectrum full width at half maximum is required.

As a red phosphor applicable to a recent light-emitting device, for example, Patent Literature 1 discloses a phosphor represented by a composition formula of SrLiAl₃N₄:Eu in Examples, and Non-Patent Literature 1 discloses a phosphor represented by a composition formula of SrLi(Al,Ga)₃N₄:Eu.

### CITATION LIST

### Patent Literature

Patent Literature 1: JP 6335884 B

### Non-Patent Literature

Non-Patent Literature 1: CHEMISTRY OF MATERIALS, Vol. 31, pp. 4614 to 4618

However, in Patent Literature 1, only phosphors having emission peak wavelengths of 650 nm or greater are obtained, and the emission intensity at 650 nm or greater, where relative luminosity is low, is high. Thus, the emission intensity at 650 nm or greater where relative luminosity is low is high, which causes a decrease in conversion efficiency of the light-emitting device. In Non-Patent Literature 1, although the emission peak wavelength is successfully shifted to blue compared to the composition of the Patent Literature 1, the quantum efficiency in a sample having an emission peak wavelength of 648 nm or less is low, which also causes a decrease in conversion efficiency of the light-emitting device.

As described above, to provide a light-emitting device having excellent conversion efficiency, a red phosphor having an appropriate emission peak wavelength and capable of efficiently converting excitation light into radiation light is required.

### SUMMARY OF INVENTION

### Technical Problem

In view of the above problems, an object of the present invention is to provide a phosphor having an appropriate emission peak wavelength and/or good absorption efficiency of excitation light, and a light-emitting device having a good color rendering property or color reproducibility and a good conversion efficiency.

### Solution to Problem

The present inventors have conducted intensive studies and found that the above problems can be solved by using a phosphor including a crystal phase having a specific composition, thereby completing the present invention.

Hereinafter, some non-limiting embodiments are provided. Note that the present invention also includes embodiments in which any of the embodiments described below further includes some or all of the features of one or more other embodiments.

Aspect 1 of the present invention relates to
a phosphor including a crystal phase having a composition represented by Formula [1]:

MA_{a-x-y-z}ReₓMY_{y}MZ_{z}MB_{b}MC_{3-w}MW_{w}D_{d} [1]
where MA includes one or more elements selected from the group consisting of Sr, Ca, and Ba,
MB includes Li,
MC includes one or more elements selected from the group consisting of B (boron), Al, Si, Ga, In, and Sc,
D is selected from the group consisting of N (nitrogen), O (oxygen), F (fluorine), Cl, Br, and I (iodine), and includes one or more elements including N (nitrogen),
Re includes one or more elements selected from the group consisting of Eu, Ce, Pr, Nd, Sm, Tb, Dy, Ho, Er, Tm, and Yb,
MY includes one or more elements selected from the group consisting of Y, La, and Lu,
MZ includes one or more elements selected from the group consisting of Na, K, and Rb,
MW includes one or more elements selected from the group consisting of Mg and Zn, and
a, b, d, x, y, z, and w each independently satisfy the following formulas:

0.7≤a≤1.3,

0.7≤b≤1.3,

3.2≤d≤4.8,

0.0<x≤0.2,

0.0<y≤0.5,

0.0≤z≤0.5,

0.0<x+y+z<a, and

0.0≤w≤0.5.

Aspect 2 of the present invention relates to
a phosphor including a crystal phase having a composition represented by Formula [2]:

MA_{a-x-y}ReₓMY_{y}MB_{b+v1}MC₃₋ᵥ₂D_{d} [2]
where MA includes one or more elements selected from the group consisting of Sr, Ca, and Ba,
MB includes Li,
MC includes one or more elements selected from the group consisting of B (boron), Al, Si, Ga, In, and Sc,
D is selected from the group consisting of N (nitrogen), O (oxygen), F (fluorine), Cl, Br and I (iodine), and includes one or more elements including N (nitrogen),
Re includes one or more elements selected from the group consisting of Eu, Ce, Pr, Nd, Sm, Tb, Dy, Ho, Er, Tm, and Yb,
MY includes one or more elements selected from the group consisting of Y, La, and Lu, and
a, b, d, x, y, v1, and v2 each independently satisfy the following formulas:

0.7≤a≤1.3,

0.7≤b≤1.3,

3.2≤d≤4.8,

0.0<x≤0.2,

0.0<y≤0.5,

0.0≤v1≤y,

0.0≤v2≤y, and

0.5y≤v1+v2≤1.5y.

Aspect 3 of the present invention relates to the phosphor according to aspect 1 or 2, in which
MC includes at least Al and Ga.

Aspect 4 of the present invention relates to the phosphor according to any one of aspects 1 to 3, in which
a crystal structure of the crystal phase having the composition represented by Formula [1] or [2] is identical to a crystal structure of SrLiAl₃N₄.

Aspect 5 of the present invention relates to the phosphor according to any one of aspects 1 to 4, having
an emission peak at a wavelength in a range of 620 nm or greater and 660 nm or less in an emission spectrum.

Aspect 6 of the present invention relates to a light-emitting device including:
a first light emitter; and a second light emitter configured to emit visible light by irradiation of light from the first light emitter, in which
the second light emitter includes the phosphor described in any one of aspects 1 to 5.

Aspect 7 of the present invention relates to the light-emitting device according to aspect 6, in which
the second light emitter further includes a yellow phosphor and/or a green phosphor.

Aspect 8 of the present invention relates to the light-emitting device according to aspect 7, in which
the yellow phosphor and/or the green phosphor includes one or more selected from the group consisting of a garnet-based phosphor, a silicate-based phosphor, a nitride phosphor, and an oxynitride phosphor.

Aspect 9 of the present invention relates to
a lighting device including the light-emitting device described in any one of aspects 6 to 8 as a light source.

Aspect 10 of the present invention relates to
an image display device including the light-emitting device described in any one of aspects 6 to 8 as a light source.

Aspect 11 of the present invention relates to
a vehicle indicator lamp including the light-emitting device described in any one of aspects 6 to 8 as a light source.

### Advantageous Effects of Invention

In a plurality of embodiments, the present invention can provide a phosphor having an appropriate emission peak wavelength and/or good absorption efficiency of excitation light, and a light-emitting device having a good color rendering property or color reproducibility and a good conversion efficiency.

### BRIEF DESCRIPTION OF DRAWINGS

FIG. 1A shows emission spectra of phosphors according to Comparative Example 1 and Examples 1 to 4. The spectra are normalized to the maximum value of an emission intensity takes as 1.0.

FIG. 1B is an enlarged view of FIG. 1A.

FIG. 2 shows unit cell volumes and measurement errors of the phosphors according to Comparative Example 1 and Examples 1 to 4.

### DESCRIPTION OF EMBODIMENTS

Hereinafter, the present invention will be described, presenting embodiments and examples. However, the present invention is not limited to the following embodiments and examples, and can be modified appropriately and carried out without departing from the gist of the present invention.

Note that a numerical range represented by using “to” in the present specification means a range including the numerical values stated before and after “to” as a lower limit value and an upper limit value. In the composition formulas of the phosphors in the present specification, each composition formula is separated by a comma (,). In addition, in a case where a plurality of elements are listed with commas (,) separating them, it is indicated that one or two or more of the listed elements may be contained in any combination and composition. For example, a composition formula “(Ca,Sr,Ba)Al₂O₄:Eu” all-inclusively means “CaAl₂O₄:Eu”, “SrAl₂O₄:Eu”, “BaAl₂O₄:Eu”, “Ca₁₋ₓSrxAl₂O₄:Eu”, “Sr₁₋ₓBaₓAl₂O₄:Eu”, “Ca₁₋ₓBaₓAl₂O₄:Eu”, and “Ca_{1-x-y}SrₓBa_{y}Al₂O₄:Eu” (where 0<x<1, 0<y<1, and 0<x+y<1 are satisfied).

### Phosphor

In one embodiment, the present invention is a phosphor (hereinafter, sometimes referred to as the “phosphor according to the first embodiment”) including a crystal phase having a composition represented by Formula [1]:

MA_{a-x-y-z}ReₓMY_{y}MZ_{z}MB_{b}MC_{3-w}MW_{w}D_{d} [1]
where in the above formula [1],
MA includes one or more elements selected from the group consisting of Sr, Ca, and Ba,
MB includes Li,
MC includes one or more elements selected from the group consisting of B (boron), Al, Si, Ga, In, and Sc,
D is selected from the group consisting of N (nitrogen), O (oxygen), F (fluorine), Cl, Br, and I (iodine), and includes one or more elements including N (nitrogen),
Re contains one or more elements selected from the group consisting of Eu, Ce, Pr, Nd, Sm, Tb, Dy, Ho, Er, Tm, and Yb,
MY includes one or more elements selected from the group consisting of Y, La, and Lu,
MZ includes one or more elements selected from the group consisting of Na, K, and Rb,
MW includes one or more elements selected from the group consisting of Mg and Zn, and
a, b, d, x, y, z, and w each independently satisfy the following formulas:

0.7≤a≤1.3,

0.7≤b≤1.3,

3.2≤d≤4.8,

0.0<x≤0.2,

0.0<y≤0.5,

0.0≤z≤0.5,

0.0<x+y+z<a, and

0.0≤w≤0.5.

In one embodiment, the present invention is a phosphor (hereinafter, sometimes referred to as the “phosphor according to the second embodiment”) including a crystal phase having a composition represented by Formula [2]:

MA_{a-x-y}ReₓMY_{y}MB_{b+v1}MC₃₋ᵥ₂D_{d} [2]
where in the above formula [2],
MA includes one or more elements selected from the group consisting of Sr, Ca, and Ba,
MB includes Li,
MC includes one or more elements selected from the group consisting of B (boron), Al, Si, Ga, In, and Sc,
D is selected from the group consisting of N (nitrogen), O (oxygen), F (fluorine), Cl, Br, and I (iodine), and includes one or more elements including N (nitrogen),
Re includes one or more elements selected from the group consisting of Eu, Ce, Pr, Nd, Sm, Tb, Dy, Ho, Er, Tm, and Yb,
MY includes one or more elements selected from the group consisting of Y, La, and Lu, and
a, b, d, x, y, v1, and v2 each independently satisfy the following formulas:

0.7≤a≤1.3,

0.7≤b≤1.3,

3.2≤d≤4.8,

0.0<x≤0.2,

0.0<y≤0.5,

0.0≤v1≤y,

0.0≤v2≤y, and

0.5y≤v1+v2≤1.5y.

In Formula [1] or [2], europium (Eu), cerium (Ce), praseodymium (Pr), neodymium (Nd), samarium (Sm), terbium (Tb), dysprosium (Dy), holmium (Ho), erbium (Er), thulium (Tm), ytterbium (Yb), and the like can be used as Re, but Re preferably includes one or more elements selected from the group consisting of Eu, Ce, Pr, Tb, and Dy, from the viewpoint of improving the emission wavelength and the emission quantum efficiency.

In an embodiment in which Re includes Eu, the proportion of europium (Eu) relative to the entire Re-activating element is preferably 50 mol % or more, more preferably 70 mol % or more, and even more preferably 90 mol % or more. When the phosphor contains an appropriate amount of the Re element, the phosphor exhibiting a good emission intensity can be obtained.

In Formula [1] or [2], MA usually includes one or more elements selected from the group consisting of calcium (Ca), strontium (Sr), and barium (Ba), and MA preferably includes Sr.

In one embodiment, the elements included in MA described above account for 70 mol % or more, preferably 80 mol % or more, more preferably 90 mol % or more, and even more preferably 95 mol % or more of the entire MA, and in a specific embodiment, MA consists of the elements described above.

In addition, in an embodiment, the element may be divalent.

In Formula [1] or [2], MB includes at least lithium (Li).

In one embodiment, Li accounts for 70 mol % or more, preferably 80 mol % or more, more preferably 90 mol % or more, and even more preferably 95 mol % or more of MB, and MB particularly preferably consists of Li.

Li in MB is usually monovalent.

A part of MB may be optionally substituted with another element, but the substituent is preferably monovalent.

In Formula [1] or [2], MC includes one or more elements selected from the group consisting of B (boron), aluminum (Al), silicon (Si), gallium (Ga), indium (In), and scandium (Sc), preferably contains Al, Ga, or Sc, and more preferably includes one or more elements selected from the group consisting of Al and Ga.

In one embodiment, the elements included in MC described above account for 70 mol % or more, preferably 80 mol % or more, more preferably 90 mol % or more, and even more preferably 95 mol % or more of the entire MC, and in a specific embodiment, MC consists of the elements described above.

In addition, in one embodiment, the element included in MC is trivalent.

In a specific embodiment, 80 mol % or more of MC is Al, preferably 90 mol % or more, more preferably 95 mol % or more, and even more preferably 98 mol % or more of MC is Al.

When 80 mol % or more of MC is Al, a red phosphor having an emission peak wavelength comparable to that of an existing red phosphor such as S/CASN and a narrow spectrum full width at half maximum can be provided. Thus, by including such a red phosphor, a light-emitting device having a good color rendering property or color reproducibility while maintaining conversion efficiency (Lm/W) comparable to or higher than that of a light-emitting device in the related art can be provided.

In another specific embodiment, MC includes Al and one or more elements selected from the group consisting of Si, Ga, In, and Sc (hereinafter, sometimes referred to as “MC²”). In this embodiment, the expression “MC₃” in Formula [1] and Formula [2] is synonymous with the expression “(Al_{1-c}MC²_{c})₃”.

In a specific embodiment, MC² preferably includes Ga, and more preferably consists of Ga. The value of c is usually more than 0.00 and 0.70 or less.

In one viewpoint, the smaller the value of c, the larger the emission peak wavelength, and the brighter the red emission. A light-emitting device including such a phosphor has a favorable value of the red color rendering property R9. From this viewpoint, c is preferably 0.67 or less, more preferably 0.60 or less, even more preferably 0.50 or less, and particularly preferably 0.40 or less, and more preferable numerical values include 0.30 or less, 0.20 or less, 0.10 or less, 0.05 or less, and 0.03 or less.

From another viewpoint, the larger the value of c, the shorter the emission peak wavelength, and the emission color has a large amount of wavelength components having high relative luminosity, and thus, the light-emitting device including such a phosphor has good conversion efficiency. In this viewpoint, the value of c in a preferred embodiment to the most preferred embodiment is 0.03 or more, 0.05 or more, 0.10 or more, 0.15 or more, 0.20 or more, 0.25 or more, 0.30 or more, 0.35 or more, 0.40 or more, 0.45 or more, 0.50 or more, 0.55 or more, 0.60 or more, and 0.65 or more in order.

When MC includes at least Al and Ga, the emission peak wavelength can be adjusted, and a phosphor having a desired emission peak wavelength can be preferably produced. In particular, in a case where Re includes Eu and the phosphor is a phosphor that emits red light, the emission peak is shifted to a shorter wavelength when MC includes Ga or the like, and a phosphor that emits more light in a region with high relative luminosity can be produced. Thus, a light-emitting device with a good color rendering property and further improved conversion efficiency can be preferably produced.

Further, when combined with the use of the MY element described below, the greater effect of changing the emission peak wavelength can be enhanced.

In Formula [1] or [2], D is selected from nitrogen (N), oxygen (O), fluorine (F), chlorine (Cl), bromine (Br), and iodine (I), and includes one or more elements including at least nitrogen (N).

In the embodiment in which D includes nitrogen (N) or oxygen (O), the total proportion of nitrogen (N) and oxygen (O) relative to the entire D is usually 70 mol % or more, preferably 80 mol % or more, more preferably 90 mol % or more, and even more preferably 95 mol % or more of the entire D.

Nitrogen (N) or oxygen (O) may partially contain another element such as fluorine (F), chlorine (Cl), bromine (Br), or iodine (I). Note that, in an embodiment of the present invention, the term “containing an element” encompasses both a form in which a contained element is substituted and a form in which a contained element is not substituted.

In Formula [1] or [2], MY includes one or more elements selected from the group consisting of Y, La, and Lu, preferably includes La or Lu, and more preferably includes La. Preferably, 80 mol % or more of MY consists of the elements described above, and more preferably, MY consists of the elements described above.

In one embodiment, MY is trivalent.

When the crystal phase includes the MY element, a phosphor having an appropriate emission peak wavelength or good absorption efficiency of excitation light can be produced, and when a light-emitting device includes such a phosphor, the light-emitting device having good conversion efficiency can be provided.

In Formula [1], MZ includes one or more elements selected from the group consisting of Na, K, and Rb, and preferably includes Na or K. Preferably, 80 mol % or more of MZ consists of the above elements, and more preferably, MZ consists of the above elements.

In one embodiment, the element included in MZ is monovalent.

In Formula [1], MW includes one or more elements selected from the group consisting of Mg and Zn, and preferably includes Mg. Further, preferably, 80 mol % or more of MW consists of the above elements, and more preferably, MW consists of the above elements.

In one embodiment, the element included in MW is divalent.

When the crystal phase having the composition represented by Formula [1] included in the phosphor according to the first embodiment includes an appropriate amount of MZ or MW, the overall charge balance is stabilized.

In addition to the intended elements, an impurity element having similar properties may be unintentionally or inevitably mixed in the MA, MB, MC, D, Re, MY, MZ, and MW. However, the present invention does not exclude these as long as the essence or effect of the present invention is not impaired or the effects of the present invention are not lost.

Here, the impurity elements may be an element that is not intended to be included in each site among the elements listed as the elements that can be included in the MA, MB, MC, D, Re, MY, MZ, and MW, or may be an element other than the elements listed above.

For example, when a phosphor is produced with the intention of a composition in which MA is composed of Ca and/or Sr, MA may be partially substituted with Ba, Mg, or other elements, due to the inevitable mixing of elements other than Ca and Sr described above into the raw materials, or due to the mixing of a trace amount of flux (fusing agent) when used in the production of the phosphor. However, the present invention does not exclude these cases as long as the essence of the present invention is not impaired or the effects of the present invention are not lost. The same applies to the case for: MB, MC, D, or Re, in place of MA described above; one or more of the elements listed as the elements that can be included in each site, in place of Ca or Sr described above; and other elements, in place of Ba and Mg described above.

O (oxygen) may be intentionally included for the purpose of maintaining the charge balance of the entire phosphor or for the purpose of adjusting the emission peak wavelength. However, even in a case where the phosphor is produced with the intention of not including 0, there are cases where O is mixed as an impurity in the raw material metals, or is introduced during the production process such as the pulverization step or the nitridation step, and O is inevitably mixed in the phosphor according to the present invention even when it is not intended.

The allowable oxygen content during the production, with the intention that Formula [1] does not include oxygen, is usually 10 mass % or less, preferably 6 mass % or less, more preferably 4 mass % or less, and even more preferably 2 mass % or less, within a tolerable range for impairment of the light emission characteristics of the phosphor.

In another embodiment, the amount of O (oxygen) included in Formula [1] or Formula [2] is 1.0 mol or less, preferably 0.8 mol or less, more preferably 0.6 mol or less, even more preferably 0.4 mol or less, and particularly preferably 0.2 mol or less, when the total of MC and MW is 3.0 mol, and the lower limit is not particularly limited.

A halogen atom may be contained in the phosphor of the present invention, as in the case of oxygen. In a case where a halogen atom is included in the phosphor, there may be a case where the halogen atom is mixed as an impurity in the raw material metals, or a case where the halogen atom is introduced during the production process such as the pulverization step or the nitridation step. In particular, in a case where a halide is used as the flux, the halogen atom may be included in the phosphor.

Examples of the halogen element mixed include fluorine, chlorine, bromine, and iodine, as described above. The halogen element is preferably 1 mass % or less, and more preferably 0.5 mass % or less, from the viewpoint of acceptable light emission characteristics of the phosphor

In Formula [1], a represents the total molar content of MA, Re, MY, and MZ, and b, d, x, y, z, and w represent the molar content of MB, D, Re, MY, MZ, and MW, respectively.

In Formula [2], a represents the total molar content of MA, Re, and MY, and b+v1, d, x, y, and 3-v2 represent the molar contents of MB, D, Re, MY, and MC, respectively.

The ideal ratio at which the crystal structure is stabilized is a case where a, b, and d are 1, 1, and 4, respectively. However, in practice, the values of a, b, and d may vary somewhat from the ideal ratio due to various causes such as single atom deficiency, a change in composition due to oxidation of the phosphor surface, a heterophase, and charge compensation. However, the present invention does not exclude these as long as the essence of the present invention is not impaired or the effects of the present invention are not lost. The ranges of allowable numerical values for a, b, d, x, y, z, w, v1, and v2 are specifically described below.

In Formula [1] or [2], the value of a is 0.7 or more, preferably 0.8 or more, and more preferably 0.9 or more, and is 1.3 or less, preferably 1.2 or less, and more preferably 1.1 or less.

In Formula [1] or [2], the value of b is 0.7 or more, preferably 0.8 or more, and more preferably 0.9 or more, and is 1.3 or less, preferably 1.2 or less, and more preferably 1.1 or less.

In Formula [1] or [2], the value of d is 3.2 or more, preferably 3.4 or more, more preferably 3.6 or more, and even more preferably 3.8 or more, and is 4.8 or less, preferably 4.6 or less, more preferably 4.4 or less, and even more preferably 4.2 or less.

When the value of a is within the above range, it is possible to obtain a phosphor having a stable crystal structure and less heterogeneous phases, and by including such a red phosphor, it is possible to provide a light-emitting device having good absorption efficiency of excitation light and good conversion efficiency of red light and the whole.

In addition, when b and d are within the above ranges, the crystal structure is stabilized. Furthermore, the value of d can be adjusted appropriately for the purpose of maintaining the charge balance of the entire phosphor.

In Formula [1] or [2], the value of x is a value of more than 0.0, preferably 0.0001 or more, and more preferably 0.001 or more, and is 0.2 or less, preferably 0.15 or less, more preferably 0.12 or less, even more preferably 0.1 or less, and still even more preferably 0.08 or less.

When the value of x is the lower limit or more, or more than 0, or the preferable lower limit or more, it is possible to obtain a phosphor having a good emission intensity. When the value of x is the upper limit or less, it is possible to obtain a phosphor in which Re is well incorporated into the crystal and easily functions as an emission center, and by including such a red phosphor, it is possible to provide a light-emitting device having good conversion efficiency.

In Formula [1] or [2], the value of y is greater than 0.0, preferably 0.0005 or more, more preferably 0.001 or more, and even more preferably 0.005 or more, and is 0.5 or less, preferably 0.4 or less, more preferably 0.3 or less, even more preferably 0.2 or less, particularly preferably 0.1 or less, extremely preferably 0.05 or less, and most preferably 0.02 or less.

When the value of y is the lower limit or more, it is possible to obtain a phosphor having a shorter emission peak wavelength or a phosphor having good absorption efficiency of excitation light, and by including such a phosphor, it is possible to provide a light-emitting device having good conversion efficiency.

When the value of y is the upper limit or less, it is possible to obtain a phosphor having a good emission intensity, and by including such a phosphor, it is possible to provide a light-emitting device having good conversion efficiency.

In Formula [1], the values of z and w are each independently 0.0 or more and 0.5 or less.

In one embodiment, the total of z and w is 0.5 times or more of y, preferably 0.7 times or more of y, more preferably 0.8 times or more of y, and even more preferably 0.9 times or more of y, and is usually 1.5 times or less of y, preferably 1.3 times or less of y, more preferably 1.2 times or less of y, and even more preferably 1.1 times or less of y.

When the values of z and w satisfy the above, it is possible to maintain the charge balance in the entire crystal phase having the composition represented by Formula [1].

When all the values are within the ranges described above, the emission peak wavelength and the full width at half maximum in the emission spectrum of the red phosphor to be obtained are good, which is preferable.

In Formula [1], the total of x, y, and z is greater than 0.0 and less than a. In the present embodiment, Re, MY, and MZ are elements that substitute the MA site in the solid solution, and a means the total of the elements included in the MA site, that is, MA, Re, MY, and MZ, and thus the total of x, y, and z does not become equal to or greater than the total value a of the MA site.

In Formula [2], v1 and v2 are each independently 0 or more and y or less. The total of v1 and v2 is 0.5y or more, preferably 0.6y or more, more preferably 0.7y or more, even more preferably 0.8y or more, and particularly preferably 0.9y or more, and is 1.5y or less, preferably 1.4y or less, more preferably 1.3y or less, even more preferably 1.2y or less, and particularly preferably 1.1y or less. When MY substitutes the MA site, the molar contents of the MB and MC sites are reduced, and thus the overall charge balance can be maintained, which chemically and electrically stabilizes the phosphor.

Note that the method for determining the elemental composition of the red phosphor is not particularly limited, and the elemental composition can be determined by a common method. The elemental composition can be determined by, for example, GD-MS, ICP spectrometry, or energy dispersive X-ray spectroscopy (EDX).

Note that the phosphors according to the first and second embodiments have a common problem and effect in the technical idea of attempting to solve the problem described above by substituting a part of the MA element with MY to obtain a phosphor having an appropriate emission wavelength, while maintaining the overall charge balance by substituting other elements or adjusting the element ratio.

### Particle Size of Phosphor

The particle size of the phosphor including the crystal phase having the composition represented by Formula [1] or [2] is usually 2 μm or more and 40 μm or less in terms of a volume-based median particle size (volume median particle size), the lower limit value is preferably 3 μm, more preferably 4 μm, and even more preferably 5 μm, and the upper limit value is preferably 35 μm, more preferably 30 μm, even more preferably 25 μm, and particularly preferably 20 km.

When the volume-based median particle size (volume median particle size) is the lower limit or more, it is preferable from the viewpoint of improving the light emission characteristics exhibited by the crystal phase in an LED package, and when the volume-based median particle size is the upper limit or less, it is preferable from the viewpoint that the crystal phase can avoid clogging of a nozzle in the production process of the LED package.

The volume-based median particle size (volume median particle size) of the crystal phase of the phosphor can be measured by a measurement technique well known to those skilled in the art, and in a preferred embodiment, the volume-based median particle size can be measured by, for example, a laser particle size analyzer. In examples of the present specification, the volume-based median particle size (volume median particle size, (d₅₀)) is defined as a particle size at which a volume-based relative particle amount is 50% when a sample is measured using a particle size distribution measuring device using a laser diffraction/scattering method as a measurement principle and a particle size distribution (cumulative distribution) is determined.

### Physical Properties of Red Phosphor

### Space Group

The crystal system (space group) of the crystal phase having the composition represented by Formula [1] or Formula [2] is not limited as long as the effects of the invention are obtained, but in one embodiment, the crystal system shows good coincidence with SrLiAl₃N₄ in the XRD pattern, and in one embodiment, the crystal system can be tetragonal P4₂/m, monoclinic P-1, or the like, and is preferably P-1. The space group in the phosphor of the present embodiment is not particularly limited as long as the average structure statistically considered in the range distinguishable by powder X-ray diffraction or single crystal X-ray diffraction shows the repeating cycle of the length described above, but the space group is preferably a group belonging to No. 2 based on “International Tables for Crystallography (Third, revised edition), Volume A SPACE-GROUP SYMMETRY”.

For example, in the phosphor according to one embodiment, the crystal structure of the crystal phase having the composition represented by Formula [1] or [2] is the same as that of SrLiAl₃N₄.

The above space group narrows the full width at half maximum (FWHM) in the emission spectrum, which allows a phosphor having good light emission efficiency to be produced.

Here, the space group can be determined in accordance with a common method, and can be determined by, for example, electron beam diffraction, X-ray diffraction structural analysis using powder or a single crystal, neutron diffraction structural analysis, or the like.

In a specific embodiment, in the phosphor according to the first or second embodiment, when the intensity of a peak appearing in a region of 2θ=38 to 39 degrees in a powder X-ray diffraction spectrum is defined as Ix and the intensity of a peak appearing in a region of 2θ=37 to 38 degrees is defined as Iy, Ix/Iy, which is a relative intensity of Ix when Iy is defined as 1, is preferably 0.140 or less, more preferably 0.120 or less, even more preferably 0.110 or less, still even more preferably 0.080 or less, particularly preferably 0.060 or less, and especially preferably 0.040 or less, and is usually 0 or more, but the smaller the better.

The peak in the region of 20=37 to 38 degrees is one of the peaks characteristic of the main phase of the phosphor according to the first or second embodiment, and a red phosphor having higher phase purity is produced when Iy is relatively high. When Ix/Iy is the upper limit or less, a phosphor having high phase purity and a narrow full width at half maximum (FWHM) in the emission spectrum can be obtained, which improves the light emission efficiency of the light-emitting device.

### Internal Quantum Efficiency of Red Phosphor

In one embodiment, the internal quantum efficiency of the phosphor is 30% or more. The internal quantum efficiency is preferably 35% or more, more preferably 40% or more, even more preferably 45% or more, particularly preferably 50% or more, and especially preferably 55% or more, and the upper limit is not limited and is preferably as high as possible, but is usually 100% or less.

The internal quantum efficiency of the red phosphor can be determined by a common method, and can be calculated from an emission spectrum measured using a spectrophotometer, for example.

### Characteristics of Emission Spectrum

The phosphor according to the first or second embodiment is excited by irradiation with light having an appropriate wavelength, and emits red light having an appropriate emission peak wavelength in the emission spectrum and an appropriate peak full width at half maximum (FWHM) in the emission spectrum. Hereinafter, the emission spectrum, the excitation wavelength, the emission peak wavelength, and the peak full width at half maximum (FWHM) in the emission spectrum will be described.

### Excitation Wavelength

The phosphor according to the first or second embodiment has an excited peak in a wavelength range of usually 270 nm or greater, preferably 300 nm or greater, more preferably 320 nm or greater, even more preferably 350 nm or greater, and particularly preferably 400 nm or greater, and is usually 550 nm or less, preferably 520 nm or less, and more preferably 500 nm or less. That is, the phosphor is excited by light in the near-ultraviolet to blue region.

Note that the shape of the emission spectrum and the description of the emission peak wavelength and the peak full width at half maximum in the emission spectrum described below are independent of the excitation wavelength. However, from the viewpoint of improving the quantum efficiency, it is preferable to perform irradiation with light having a wavelength in the above range in which the efficiency of absorption and excitation is good.

### Emission Peak Wavelength

In one embodiment, the red phosphor has an emission spectrum having an emission peak wavelength in a range of 620 nm or greater and 660 nm or less in the emission spectrum.

In a specific embodiment, the emission spectrum of the red phosphor preferably includes at least one emission peak in a range of 625 nm or greater, more preferably 630 nm or greater, even more preferably 635 nm or greater, still even more preferably 640 nm or greater, and extremely preferably 645 nm or greater. A light-emitting device including a red phosphor having at least one emission peak with an emission peak wavelength equal to or greater than the lower limit has a good red color rendering property or color reproducibility, and is suitable for applications such as a backlight for an image display device (display). Alternatively, the light-emitting device can emit clear red light, and is suitable for use as a brake lamp or the like.

In another specific embodiment, the emission spectrum preferably includes one or more emission peaks at or below 655 nm, more preferably at or below 650 nm, even more preferably at or below 648 nm, still even more preferably at or below 645 nm, particularly preferably at or below 640 nm, and extremely particularly preferably at or below 637 nm. A red phosphor having an emission spectrum with one or more emission peaks at or below the upper limit has a low emission intensity in a wavelength range of around 700 nm where the relative luminosity is low. A light-emitting device including such a red phosphor has good conversion efficiency and is suitable for use in a lighting device, for example.

The method for adjusting the emission peak wavelength is not particularly limited, and for example, the emission peak wavelength can be adjusted while keeping the peak full width at half maximum in the emission spectrum narrow by adjusting the constitution of the MC elements. In a specific embodiment, the emission peak wavelength can be shifted toward a longer wavelength by increasing the proportion of Al in MC, and the emission peak wavelength can be shifted toward a shorter wavelength by increasing the proportion of elements other than Al in a part of MC in Formula [1] or Formula [2].

### Peak Full Width at Half Maximum in Emission Spectrum

The phosphor according to the first or second embodiment has a peak full width at half maximum in the emission spectrum of usually 70 nm or less, preferably 65 nm or less, more preferably 60 nm or less, even more preferably 57 nm or less, particularly preferably 55 nm or less, and most preferably 50 nm or less, and is usually 10 nm or more.

When a red phosphor having a peak full width at half maximum in the emission spectrum within the above range is used, the color reproduction range can be widened without reducing the color purity in an image display device such as a liquid crystal display.

In addition, when the emission peak wavelength and the peak full width at half maximum in the emission spectrum are equal to or less than the upper limits, a red phosphor having relatively high relative luminosity in the emission wavelength region can be provided, and a light-emitting device having high conversion efficiency can be provided by using such a red phosphor in the light-emitting device.

Note that to excite the red phosphor with light having a wavelength around 450 nm, for example, a GaN-based LED can be used. The emission spectrum of the red phosphor can be measured, and the emission peak wavelength, the peak relative intensity, and the peak full width at half maximum in the emission spectrum can be calculated, using a commercially available spectrum measuring apparatus, such as a fluorescence measuring apparatus including a light source having an emission wavelength of 300 to 400 nm, such as a commercially available xenon lamp, and a general photodetector.

In one embodiment, in the light-emitting device, the red phosphor preferably satisfies a relationship of y≤184−0.2x, where x (nm) is an emission peak wavelength, and y (nm) is a peak full width at half maximum in the emission spectrum.

When a phosphor in which the emission peak wavelength and the peak full width at half maximum of the phosphor satisfy the above formula is used, the conversion efficiency of the light-emitting device can be improved.

### Method for Producing Phosphor

The phosphor of the present embodiment can be synthesized by mixing and heating raw materials of the respective elements constituting the phosphor in such a manner that the proportions of the respective elements satisfy Formula [1] or Formula [2].

### Phosphor Raw Material

The phosphor raw material serving as a supply source of each element (MA, MB, MC, Re, MY, MZ, MW) is not particularly limited, and examples thereof include a substance of each element, an oxide, a nitride, a hydroxide, a halide such as a chloride or a fluoride, an inorganic salt such as a sulfate, a nitrate, or a phosphate, and an organic acid salt such as an acetate. In addition, a compound containing two or more of the above element groups may be used. Each compound may be a hydrate or the like.

Note that, in the examples described below, nitrides were used as the phosphor raw materials for the elements other than MW, and a fluoride was used as the phosphor raw material for the MW element.

The method for acquiring each phosphor raw material is not particularly limited, and a commercially available product can be purchased and used.

The purity of each phosphor raw material is not particularly limited, but from the viewpoint of making the element ratio strict and from the viewpoint of avoiding the formation of a heterophase due to an impurity, the purity is preferably as high as possible, and is usually 90 mol % or more, preferably 95 mol % or more, more preferably 97 mol % or more, and even more preferably 99 mol % or more, and the upper limit is not particularly limited, but is usually 100 mol % or less, and an impurity that is inevitably mixed may be included.

In the examples described below, phosphor raw materials each having a purity of 95 mol % or more were used.

Oxygen (O), nitrogen (N), or a halogen element that can be included in the D element can be supplied by using an oxide, a nitride, a halide, or the like as a phosphor raw material serving as a supply source of each of the elements, and can be appropriately included by setting an oxygen- or nitrogen-containing atmosphere during a synthesis reaction.

### Mixing Step

A mixing method of the phosphor raw materials is not particularly limited, and a common method can be used. For example, the phosphor raw materials are weighed to yield a target composition, and are sufficiently mixed using a ball mill or the like to produce a phosphor raw material mixture. The mixing method is not particularly limited, and specific examples thereof include the following methods (a) and (b).
(a) A dry mixing method in which pulverization and mixing are combined to pulverize and mix the phosphor raw materials described above. In the pulverization, a dry pulverizer such as a hammer mill, a roll mill, a ball mill, or a jet mill, or a mortar and a pestle, is used. In mixing, a mixer such as a ribbon blender, a V-type blender, or a Henschel mixer, or a mortar and a pestle is used.
(b) A wet mixing method in which a solvent or a dispersion medium such as water is added to the phosphor raw materials, and the mixture is mixed using, for example, a pulverizer, a mortar and a pestle, or an evaporation dish and a stirring rod to form a solution or slurry, and then the solution or slurry is dried by spray drying, heat drying, natural drying, or the like.

The mixing of the phosphor raw materials may be carried out by any of the dry mixing methods and wet mixing methods, and for avoiding contamination of the phosphor raw materials by moisture, dry mixing methods and wet mixing methods using a non-aqueous solvent are preferred.

Note that in the examples described below, the method (a) was adopted.

### Heating Step

In the heating step (hereinafter, also referred to as a firing step), for example, the phosphor raw material mixture yielded in the mixing step is put in a crucible, and then heated at a temperature of 500° C. to 1200° C. The temperature in the heating step is preferably 600° C. or higher, and more preferably 700° C. or higher, and is preferably 1000° C. or lower, and more preferably 950° C. or lower, and may be 900° C. or lower.

When the heating temperature (hereinafter, also referred to as a firing temperature) is set to a low temperature, particularly to 950° C. or lower, a phosphor having a high phase purity of the composition represented by Formula [1] and a high emission intensity is obtained. The reason for this is that, while a substance including Li, Mg, Na, or the like having a high vapor pressure is likely to volatilize at a high temperature such as 1000° C. or higher or 1100° C. or higher and the ratio of each element is likely to vary in the synthesis reaction of the phosphor, the variation in the ratio of each element can be suppressed by performing the synthesis at a low temperature such as 950° C. or lower.

The pressure in the heating step may be normal pressure or a pressurized state as long as the target phosphor is produced, but pressurization is preferable for preventing volatilization of elements contained in the phosphor raw materials. In a case of applying a pressure, the pressure is usually 0.1 MPa or more and 200 MPa or less, and preferably 100 MPa or less. When the pressure is within the above range, good reactivity of the phosphor raw materials can be ensured.

The method of pressurization is not limited, and for example, a method of heating a sealed container, a method of mechanically pressurizing, a method of using a gas pressure, or the like can be used.

The material of the crucible is preferably one that does not react with the phosphor raw materials or a reactant, and examples thereof include: ceramics such as alumina, quartz, boron nitride, silicon carbide, and silicon nitride; metals such as nickel (Ni), platinum (Pt), molybdenum (Mo), tungsten (W), tantalum (Ta), niobium (Nb), iridium (Ir), and rhodium (Rh); and alloys containing these as main components.

The heating is preferably performed in an inert atmosphere, and a gas containing nitrogen, argon, helium, or the like as a main component can be used.

Note that in the examples described below, heating was performed in a nitrogen atmosphere.

In the heating step, heating is performed in the above temperature zone for usually 10 minutes to 200 hours, preferably 1 hour to 100 hours, and more preferably 2 hours to 50 hours. The heating step may be performed once or a plurality of times. Examples of the aspect in which the heating step is performed a plurality of times include an aspect including an annealing step of performing heating under pressure to repair a defect, and an aspect in which primary heating for obtaining primary particles or an intermediate is performed, and then secondary heating for obtaining secondary particles or a final product is performed.

Thus, the phosphor of the present embodiment is obtained.

### Light-Emitting Device

In one embodiment, the present invention is a light-emitting device including: a first light emitter; and a second light emitter that emits visible light by irradiation with light from the first light emitter, in which
the second light emitter includes the phosphor described in the first or second embodiment.

The description of the phosphor described above can be applied as it is to the constitution and characteristics of the phosphor described in the first or second embodiment included in the light-emitting device of the present embodiment.

Here, as the second light emitter, one type of phosphor may be used singly, or two or more types of phosphors may be used in any combination and proportions. Alternatively, the second light emitter may include a phosphor other than the phosphor according to the first or second embodiment.

The light-emitting device in the present embodiment includes at least the phosphor described in the first or second embodiment as the second light emitter, and can further use a yellow phosphor that emits yellow fluorescence, a green phosphor that emits green fluorescence, or a red phosphor that emits fluorescence in a red region (orange or red) (a red phosphor different from the phosphor described in the first or second embodiment) under irradiation with light from an excitation light source.

In a specific embodiment, the light-emitting device according to the present invention is a light-emitting device in which the second light emitter further includes a yellow phosphor and/or a green phosphor.

Specifically, in a case of configuring a light-emitting device, the yellow phosphor preferably has an emission peak in a wavelength range of 550 nm or greater and 600 nm or less, and the green phosphor preferably has an emission peak in a wavelength range of 500 nm or greater and 560 nm or less. The orange or red phosphor has an emission peak in a wavelength range of usually 615 nm or greater, preferably 620 nm or greater, more preferably 625 nm or greater, and even more preferably 630 nm or greater, and usually 660 nm or less, preferably 650 nm or less, more preferably 645 nm or less, and even more preferably 640 nm or less.

When phosphors having the above wavelength regions are appropriately combined, it is possible to provide a light-emitting device exhibiting excellent color reproducibility. Note that, as the excitation light source, a light source having an emission peak in a wavelength range of shorter than 420 nm may be used.

Hereinafter, a form of a light-emitting device in which at least the phosphor described in the first or second embodiment is used as a red phosphor will be described, but the present embodiment is not limited thereto.

In the above case, the light-emitting device of the present embodiment can be, for example, in the following form (X), (Y), or (Z).
(X) An aspect including a first light emitter and a second light emitter, in which the second light emitter includes at least the phosphor described in the first or second embodiment, and further includes at least one type of phosphor (yellow phosphor) having an emission peak in a wavelength range of 550 nm or greater and 600 nm or less.
(Y) An aspect including a first light emitter and a second light emitter, in which the second light emitter includes at least the phosphor described in the first or second embodiment, and further includes at least one type of phosphor (green phosphor) having an emission peak in a wavelength range of 500 nm or greater and 560 nm or less.
(Z) An aspect including a first light emitter and a second light emitter, in which the second light emitter includes at least the phosphor described in the first or second embodiment, and further includes at least one type of phosphor (yellow phosphor) having an emission peak in a wavelength range of 550 nm or greater and 600 nm or less, and at least one type of phosphor (green phosphor) having an emission peak in a wavelength range of 500 nm or greater and 560 nm or less.

As the yellow phosphor and/or the green phosphor in the above form, commercially available phosphors can be used, and for example, a garnet-based phosphor, a silicate-based phosphor, a nitride phosphor, an oxynitride phosphor, or the like can be used. In a specific embodiment, the yellow phosphor and/or the green phosphor include one or more selected from the group consisting of a garnet-based phosphor, a silicate-based phosphor, a nitride phosphor, and an oxynitride phosphor.

### Yellow Phosphor

Examples of the garnet-based phosphor that can be used for the yellow phosphor include (Y,Gd,Lu,Tb,La)₃(Al,Ga)₅O₁₂:(Ce,Eu,Nd), examples of the silicate-based phosphor include (Ba,Sr,Ca,Mg)₂SiO₄:(Eu,Ce), and examples of the nitride phosphor and the oxynitride phosphor include (Ba,Ca,Mg)Si₂O₂N₂:Eu (SION-based phosphor), (Li,Ca)₂(Si,Al)₁₂(O,N)₁₆:(Ce,Eu) (a-SiAlON phosphor), (Ca,Sr)AlSi₄(O,N)₇:(Ce,Eu) (1147 phosphor), and (La,Ca,Y,Gd)₃(Al,Si)₆Nri:(Ce,Eu) (LSN phosphor).

One of these may be used alone, or two or more thereof may be used in combination.

As the yellow phosphor, a garnet-based phosphor is preferable among the above phosphors, and among them, a YAG-based phosphor represented by Y₃Al₅O₁₂:Ce is most preferable.

### Green Phosphor

Examples of the garnet-based phosphor that can be used for the green phosphor include (Y,Gd,Lu,Tb,La)₃(Al,Ga)₅O₁₂:(Ce,Eu,Nd), and Ca₃(Sc,Mg)₂Si₃O₁₂:(Ce,Eu) (CSMS phosphor), examples of the silicate-based phosphor include (Ba,Sr,Ca,Mg)₃SiO₁₀:(Eu,Ce), and (Ba,Sr,Ca,Mg)₂SiO₄:(Ce,Eu) (BSS phosphor), examples of the oxide phosphor include (Ca,Sr,Ba,Mg)(Sc,Zn)₂O₄:(Ce,Eu) (CASO phosphor), and examples of the nitride phosphor and the oxynitride phosphor include (Ba,Sr,Ca,Mg)Si₂O₂N₂:(Eu,Ce), Si_{6-z}Al_{z}O_{z}N_{8-z}:(Eu,Ce) (β-SiAlON phosphor) (0<z<1), (Ba,Sr,Ca,Mg,La)₃(Si,Al)₆O₁₂N₂:(Eu,Ce) (BSON phosphor), and (La,Ca,Y,Gd)₃(Al,Si)₆Nri:(Ce,Eu) (LSN phosphor).

One of these may be used alone, or two or more thereof may be used in combination.

### Red Phosphor

As the red phosphor, at least the phosphor described in the first or second embodiment is used, but in addition to the phosphor of the present embodiment, other orange or red phosphors such as a garnet-based phosphor, a sulfide phosphor, a nanoparticle phosphor, a nitride phosphor, and an oxynitride phosphor can be used. As other orange or red phosphors, for example, the following phosphors can be used.

Examples of the sulfide phosphor include (Sr,Ca)S:Eu (CAS phosphor), and La₂O₂S:Eu (LOS phosphor), examples of the garnet-based phosphor include (Y,Lu,Gd,Tb)₃Mg₂AlSi₂O₁₂:Ce, and examples of the nanoparticles include CdSe, examples of the nitride or oxynitride phosphors include (Sr,Ca) AlSiN₃:Eu (S/CASN phosphor), (CaAlSiN₃)₁₋ₓ(SiO₂N₂)ₓ:Eu (CASON phosphor), (La,Ca)₃(Al,Si)₆N₁₁:Eu (LSN phosphor), (Ca,Sr,Ba)₂Si₅(N,O)₈:Eu (258 phosphor), (Sr,Ca)Al₁₊ₓSi₄₋ₓOₓN₇₋ₓ:Eu (1147 phosphor), Mₓ(Si,Al)₁₂(O,N)₁₆:Eu (M is Ca, Sr, or the like) (a-SiAlON phosphor), and Li(Sr,Ba)Al₃N₄:Eu (all x's satisfy 0<x<1).

One of these may be used alone, or two or more thereof may be used in combination.

### Configuration of Light-Emitting Device

The light-emitting device according to the present embodiment has a first light emitter (excitation light source), at least the phosphor described in the first or second embodiment can be used as a second light emitter, the configuration thereof is not limited, and any known device configuration can be adopted.

As the first light emitter, an LED element having a light-emitting structure formed of various semiconductors such as a GaN-based semiconductor, a ZnO-based semiconductor, and a SiC-based semiconductor can be used.

Examples of the device configuration and the embodiment of the light-emitting device include those described in JP 2007-291352 A.

In addition, the LED element may be fixed to a package such as a bullet-shaped package or an SMD type package, or may be directly fixed onto a circuit board as in a case of a chip-on-board type light-emitting device. The form of optical coupling between the LED element and the phosphor is not limited, and the space between the two may be simply filled with a transparent medium (including air), or an optical element such as a lens, an optical fiber, a light guide plate, or a reflection mirror may be interposed between the two. The structure in which the phosphor particles are dispersed in a translucent matrix is typically formed by curing a resin paste in which the particulate phosphor is dispersed. In addition to the structure in which the LED element is embedded in the cured product of the paste, various structures can be adopted, such as a structure in which the cured product in a membrane shape covers a part of the surface of the LED element, and a structure in which a film formed of the cured product is disposed at a position away from the LED element.

### Application of Light-Emitting Device

The application of the light-emitting device is not particularly limited, and the light-emitting device can be used in various fields where a normal light-emitting device is used. However, a light-emitting device having a high color rendering property can be particularly suitably used as a light source of a lighting device or an image display device.

The light-emitting device including the red phosphor having an appropriate emission wavelength can also be used for a vehicle indicator lamp of red or a vehicle indicator lamp of white including the red.

### Lighting Device

In one embodiment, the present invention can be a lighting device including the light-emitting device as a light source.

In a case where the light-emitting device is applied to a lighting device, the specific configuration of the lighting device is not limited, and the light-emitting device as described above only needs to be appropriately incorporated into a known lighting device. Examples thereof include a surface emitting lighting device in which a large number of light-emitting devices are arranged on the bottom surface of a holding case.

### Image Display Device

In one embodiment, the present invention can be an image display device including the light-emitting device as a light source.

In a case where the light-emitting device is used as a light source of an image display device, the specific configuration of the image display device is not limited, but the light-emitting device is preferably used together with a color filter. For example, in a case of a color image display device using a color liquid crystal display element as the image display device, the image display device can be formed by using the light-emitting device as a backlight and combining an optical shutter using a liquid crystal and a color filter having red, green, and blue pixels.

### Vehicle Indicator Lamp

In one embodiment, the present invention can be a vehicle indicator lamp including the light-emitting device as a light source.

The light-emitting device used in the vehicle indicator lamp is preferably a light-emitting device that emits white light in a specific embodiment. In the light-emitting device that emits white light, light emitted from the light-emitting device preferably has a deviation duv (also referred to as Δuv) of the color of light from the blackbody radiation locus of −0.0200 to 0.0200 and a color temperature of 5000 K or more and 30000 K or less.

The light-emitting device used in the vehicle indicator lamp is preferably a light-emitting device that emits red light in a specific embodiment. In the embodiment, for example, the light-emitting device may absorb blue light emitted from a blue LED chip to emit red light, thereby serving as a vehicle indicator lamp of red light.

The vehicle indicator lamp includes a lighting device provided in a vehicle for the purpose of providing some indication to other vehicles, people, and the like, such as a head lamp, a side lamp, a back lamp, a turn signal, a brake lamp, and a fog lamp of the vehicle.

### EXAMPLES

Hereinafter, some specific embodiments of the present invention will be described by way of Examples, but as long as the gist of the present invention is not exceeded, the present invention is not limited to the following Examples.

### Measurement Method

### Measurement of Emission Spectrum

The emission spectrum was measured with a spectrofluorophotometer FP8500 (available from JASCO Corporation) under the following measurement conditions.
Light source: xenon lamp
Excitation wavelength: 455 nm
Measurement wavelength range: 380 to 780 nm
Measurement interval: 1.0 nm

The values of the chromaticity coordinates were calculated from the emission spectrum data of 480 nm to 780 nm using the CIE1931 XYZ equation functions.

### Measurement of Reflectance

The reflectance was measured with an ultraviolet-visible spectrophotometer (available from JASCO Corporation, V-750) under the following measurement conditions. The reflectance is a reflection value for light of 455 nm, with the reflection value of a standard reflector being 100%.
Light source: deuterium lamp, halogen lamp
Measurement wavelength range: 380 to 780 nm
Measurement interval: 1.0 nm

### Unit Cell Volume

The unit cell volume was calculated by X-ray diffraction (XRD) and Rietveld structural analysis. XRD was precisely measured with a powder X-ray diffractometer X'Pert PRO MPD (available from PANalytical). The measurement conditions were as follows.
CuKα tube used
X-ray output=45 kV, 40 mA
Divergence slit=automatic
Detector=high-speed semiconductor array detector X'Celerator
Searching range 20=10 to 150 degrees
Read width=0.008 degrees

The unit cell volume was calculated by refining the lattice constant using “RIETAN-FP” as Rietveld analysis software.

### Spectral Efficiency in Red Region

The emission spectral efficiency in the red region was evaluated. Based on the emission spectrum of each phosphor, a value obtained by integrating the product of the emission intensity and the photopic relative luminosity for each of the wavelengths in the range of 550 to 780 nm was divided by a value obtained by integrating only the emission intensity for each of the wavelengths in the range of 550 to 780 nm, and the obtained value was multiplied by the photopic maximum relative luminosity 683 Lm/W to calculate a numerical value.

### Production of Phosphor

### Comparative Example 1

An exemplary red phosphor used in the light-emitting device according to one embodiment of the present invention or a comparative example was produced.

With reference to JP 2017-008130 A, Chemistry of Materials 2019-31 (12), 4614 to 4618, and the like, nitrides of the respective elements were dry-mixed in such a manner that the molar ratios of the respective elements were the ratios shown in Table 1, the mixture was placed in a crucible made of boron nitride, and the crucible was placed in a firing furnace. The atmosphere in the firing furnace was purged with nitrogen gas, the nitrogen gas pressure was set to 0.9 MPa, the inside of the firing furnace was heated to 850° C., and the temperature was maintained at 850° C. for 5 hours to produce a phosphor according to Comparative Example 1.

### Examples 1 to 4

Phosphors according to Examples 1 to 4 were produced in the same manner as in Comparative Example 1, except that La, Na, and K raw materials were used as appropriate, and the raw materials were mixed in such a manner that the molar ratios of the respective element were the ratios shown in Table 1.

TABLE 1

| | Sr | La | Na | K | Li | Al | Ga | Eu |
|---|---|---|---|---|---|---|---|---|
| Comparative | 0.990 | 0.000 | 0.000 | 0.000 | 1.000 | 2.100 | 0.900 | 0.010 |
| Example 1 | | | | | | | | |
| Example 1 | 0.790 | 0.100 | 0.000 | 0.100 | 1.000 | 2.100 | 0.900 | 0.010 |
| Example 2 | 0.790 | 0.100 | 0.100 | 0.000 | 1.000 | 2.100 | 0.900 | 0.010 |
| Example 3 | 0.890 | 0.100 | 0.000 | 0.000 | 1.050 | 2.065 | 0.885 | 0.010 |
| Example 4 | 0.790 | 0.200 | 0.000 | 0.000 | 1.100 | 2.030 | 0.870 | 0.010 |

### Comparative Example 2 and Examples 5 to 8

Phosphors according to Comparative Example 2 and Examples 5 to 8 were produced in the same manner as in Comparative Example 1 except that the raw materials were mixed in such a manner that the molar ratios of the respective elements were the ratios shown in Table 2, and the temperature in the firing furnace was changed to 830° C. The results of component analysis of the phosphors according to Comparative Example 2 and Examples 5 to 8 by the SEM-EDS method are shown in Table 3.

The conditions of the SEM-EDS were as follows.

Device: S-3400N available from Hitachi, Ltd. and Noran System available from Thermo Fisher Scientific

Measurement conditions: BSE image, acceleration voltage 20 kV, low vacuum (90 Pa)

Analysis: 2 fields of view, EDS measurement of samples of n number of 29 to 41. In the atomic ratios (at %) of the measurement result, the Sr composition ratio and the La composition ratio were calculated based on the total composition ratio of Al+Ga

TABLE 2

| | Sr | La | Al | Ga |
|---|---|---|---|---|
| Comparative | 0.990 | 0.000 | 2.100 | 0.900 |
| Example 2 | | | | |
| Example 5 | 0.980 | 0.010 | 2.090 | 0.896 |
| Example 6 | 0.940 | 0.050 | 2.048 | 0.878 |
| Example 7 | 0.890 | 0.100 | 1.995 | 0.855 |
| Example 8 | 0.790 | 0.200 | 1.890 | 0.810 |

TABLE 3

| | Sr | La | Al | Ga |
|---|---|---|---|---|
| Comparative | 0.976 | 0.013 | 2.172 | 0.828 |
| Example 2 | | | | |
| Example 5 | 0.961 | 0.018 | 2.165 | 0.830 |
| Example 6 | 0.966 | 0.058 | 2.086 | 0.889 |
| Example 7 | 0.930 | 0.067 | 2.089 | 0.861 |
| Example 8 | 0.769 | 0.194 | 1.986 | 0.914 |

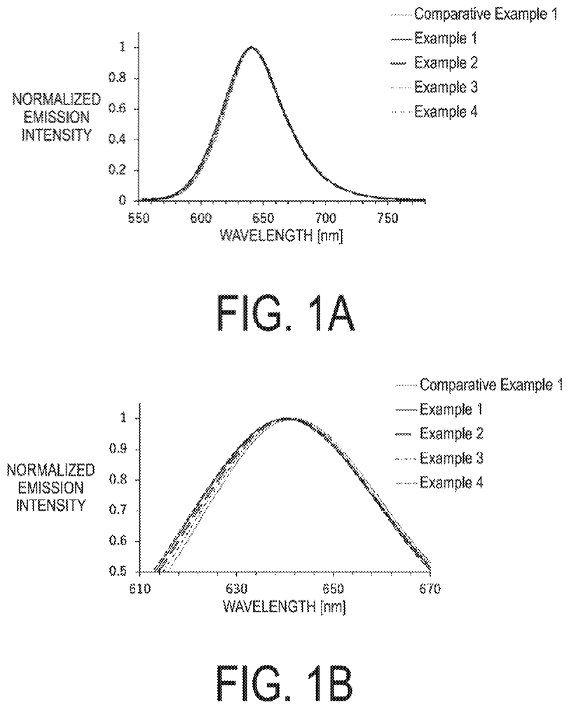

Various properties of the phosphors according to Comparative Example 1 and Examples 1 to 4 are shown in Table 4. Various properties of the phosphors according to Comparative Example 2 and Examples 5 to 8 are shown in Table 5. The emission spectra of the phosphors according to Comparative Example 1 and Examples 1 to 4, which were normalized to the maximum value of the emission intensity taken as 1.0 are shown in FIG. 1A, and enlarged views thereof are shown in FIG. 1B.

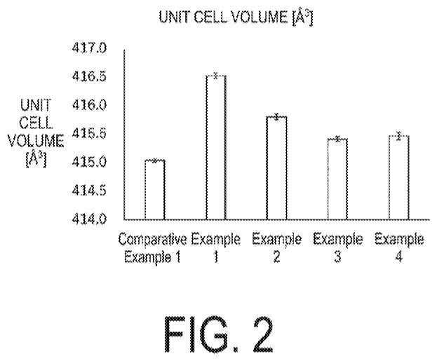

The unit cell volumes of the phosphors according to Comparative Example 1 and Examples 1 to 4 are shown in Table 4 and FIG. 2.

When the component analysis of the phosphor according to Example 3 was performed by a scanning electron microscope (SEM)-EDX (energy dispersive X-ray spectroscopy) method, Sr: La: Al: Ga=0.89:0.14:2.03:0.92 was obtained, and the molar ratios of the respective elements were substantially the same as the mixing ratios of the raw materials. Note that the powder X-ray diffraction patterns of the phosphors according to Examples 1 to 4 all showed good agreement with SrLiAl₃N₄:Eu, and thus it was inferred that the molar ratio of nitrogen atoms was about 4 when the total of the molar ratios of Al and Ga was 3.

From the fact that the unit cell volume changes and the fact that the molar ratios of the elements reflect the ratios at the time of mixing the raw materials, it is considered that the solid-solution substitution from MA to MY occurs as intended.

As can be seen from Table 3, the molar ratios of the respective elements in the phosphors according to Comparative Example 2 and Examples 5 to 8 were substantially the same as the mixing ratios of the raw materials. Note that, although La is not 0 in Comparative Example 2, this is a baseline, and it can be considered that La is not included in the phosphor according to Comparative Example 2.

TABLE 4

| | Emission peak | | | | 455 nm reflection, | | | 550 to 780 | | |
|---|---|---|---|---|---|---|---|---|---|---|
| | | Full width | | | absorption | | | nm | | |
| | Wave- | at half | Chromaticity | | | Absorption | 780 nm | Spectral | Unit cell | |
| | length | maximum | coordinates | | Reflectance | rate | Reflectance | efficiency | Volume | Error |
| | [nm] | [nm] | x | y | [%] | [%] | [%] | [Lm/Wopt] | [Å³] | [Å³] |
| Comparative | 643 | 55 | 0.673 | 0.311 | 36 | 64 | 72.8 | 146 | 415.05 | 0.03 |
| Example 1 | | | | | | | | | | |
| Example 1 | 642 | 57 | 0.646 | 0.310 | 35 | 65 | 69.9 | 157 | 416.53 | 0.05 |
| Example 2 | 642 | 56 | 0.654 | 0.310 | 33 | 67 | 68.4 | 154 | 415.81 | 0.05 |
| Example 3 | 642 | 56 | 0.652 | 0.309 | 29 | 71 | 68.3 | 151 | 415.42 | 0.04 |
| Example 4 | 641 | 57 | 0.621 | 0.307 | 27 | 73 | 65.4 | 160 | 415.47 | 0.06 |

TABLE 5

| | | | | | 455 nm reflection, | | | |
|---|---|---|---|---|---|---|---|---|
| | Emission peak | | | | absorption | | | |
| | | Full width at | Chromaticity | | | Absorption | Unit cell | |
| | Wavelength | half maximum | coordinates | | Reflectance | rate | Volume | Error |
| | [nm] | [nm] | x | y | [%] | [%] | [Å³] | [Å³] |
| Comparative | 644 | 55 | 0.679 | 0.310 | 34 | 66 | 414.99 | 0.001 |
| Example 2 | | | | | | | | |
| Example 5 | 643 | 56 | 0.677 | 0.311 | 32 | 68 | 415.43 | 0.001 |
| Example 6 | 643 | 56 | 0.671 | 0.312 | 33 | 67 | 415.94 | 0.001 |
| Example 7 | 642 | 57 | 0.667 | 0.314 | 29 | 71 | 416.32 | 0.001 |
| Example 8 | 640 | 58 | 0.645 | 0.314 | 25 | 75 | 416.75 | 0.002 |

As can be seen from Table 4, the phosphors according to Examples 1 to 4 all had significantly improved absorption efficiency of the excitation light and significantly improved spectral efficiency in the red region as compared with the phosphor according to Comparative Example 1. In addition, the unit cell volume changed, but this is considered to be due to the fact that an element different from that of the phosphor according to Comparative Example 1, that is, MY, MZ, or MW was solid-solved.

As can be seen from Table 5, the phosphors according to Examples 5 to 8 all had significantly improved absorption efficiency of excitation light as compared with the phosphor according to Comparative Example 2. In addition, the unit cell volume changed, but this is considered to be due to the fact that an element different from that of the phosphor according to Comparative Example 2, that is, MY, was incorporated to be solid solution.

As described above, according to the present embodiment, it is possible to provide a phosphor having an appropriate emission peak wavelength and/or good absorption efficiency of excitation light. In addition, with such a phosphor, it is possible to provide a light-emitting device, a lighting device, an image display device, and/or a vehicle indicator lamp having a good color rendering property or color reproducibility and good conversion efficiency.

Although various embodiments have been described above, it is needless to say that the present invention is not limited to such embodiments. It will be apparent to those skilled in the art that various changes and modifications can be made within the scope of the claims, and it should be understood that such changes and modifications naturally fall within the technical scope of the present invention. In addition, the constituent elements in the embodiments may be appropriately combined without departing from the gist of the invention.

Note that the present application is based on Japanese Patent Application (JP 2023-194412) filed on Nov. 15, 2023, the content of which is incorporated herein by reference.

### INDUSTRIAL APPLICABILITY

The phosphor of the present invention is a red phosphor having an appropriate emission peak wavelength and efficiently converting excitation light into radiation light, and can provide a light-emitting device having good conversion efficiency, and thus can be used for a lighting device, an image display device, a vehicle indicator lamp, and the like.

1. A phosphor comprising a crystal phase having a composition represented by Formula [1]:
MA_{a-x-y-z}ReₓMY_{y}MZ_{z}MBbMC_{3-w}MW_{w}D_{d} [1]
where
MA includes one or more elements selected from the group consisting of Sr, Ca, and Ba,
MB includes Li,
MC includes one or more elements selected from the group consisting of B (boron), Al, Si, Ga, In, and Sc,
D is selected from the group consisting of N (nitrogen), O (oxygen), F (fluorine), Cl, Br, and I (iodine), and includes one or more elements including N (nitrogen),
Re includes one or more elements selected from the group consisting of Eu, Ce, Pr, Nd, Sm, Tb, Dy, Ho, Er, Tm, and Yb,
MY includes one or more elements selected from the group consisting of Y, La, and Lu,
MZ includes one or more elements selected from the group consisting of Na, K, and Rb,
MW includes one or more elements selected from the group consisting of Mg and Zn, and
a, b, d, x, y, z, and w each independently satisfy the following formulas:
0.7≤a≤1.3,
0.7≤b≤1.3,
3.2≤d≤4.8,
0.0<x≤0.2,
0.0<y≤0.5,
0.0≤z≤0.5,
0.0<x+y+z<a, and
0.0≤w≤0.5.

2. A phosphor comprising a crystal phase having a composition represented by Formula [2]:
MA_{a-x-y}ReₓMY_{y}MB_{b+v1}MC₃₋ᵥ₂D_{d} [2]
where MA includes one or more elements selected from the group consisting of Sr, Ca, and Ba,
MB includes Li,
MC includes one or more elements selected from the group consisting of B (boron), Al, Si, Ga, In, and Sc,
D is selected from the group consisting of N (nitrogen), O (oxygen), F (fluorine), Cl, Br, and I (iodine), and includes one or more elements including N (nitrogen),
Re includes one or more elements selected from the group consisting of Eu, Ce, Pr, Nd, Sm, Tb, Dy, Ho, Er, Tm, and Yb,
MY includes one or more elements selected from the group consisting of Y, La, and Lu, and
a, b, d, x, y, v1, and v2 each independently satisfy the following formulas:
0.7≤a≤1.3,
0.7≤b≤1.3,
3.2≤d≤4.8,
0.0<x≤0.2,
0.0<y≤0.5,
0.0≤v1≤y,
0.0≤v2≤y, and
0.5y≤v1+v2≤1.5y.

3. The phosphor according to claim 1, wherein MC includes at least Al and Ga.

4. The phosphor according to claim 1, wherein a crystal structure of the crystal phase having the composition represented by Formula [1] is identical to a crystal structure of SrLiAl₃N₄.

5. The phosphor according to claim 1, having an emission peak at a wavelength in a range of 620 nm or greater and 660 nm or less in an emission spectrum.

6. A light-emitting device comprising: a first light emitter; and a second light emitter configured to emit visible light by irradiation with light from the first light emitter;
wherein the second light emitter includes the phosphor described in claim 1.

7. The light-emitting device according to claim 6, wherein the second light emitter further includes a yellow phosphor and/or a green phosphor.

8. The light-emitting device according to claim 7, wherein the yellow phosphor and/or the green phosphor includes one or more selected from the group consisting of a garnet-based phosphor, a silicate-based phosphor, a nitride phosphor, and an oxynitride phosphor.

9. A lighting device comprising the light-emitting device described in claim 6 as a light source.

10. An image display device comprising the light-emitting device described in claim 6 as a light source.

11. A vehicle indicator lamp comprising the light-emitting device described in claim 6 as a light source.

12. The phosphor according to claim 2, wherein MC includes at least Al and Ga.

13. The phosphor according to claim 2, wherein a crystal structure of the crystal phase having the composition represented by Formula [2] is identical to a crystal structure of SrLiAl₃N₄.

14. The phosphor according to claim 2, having an emission peak at a wavelength in a range of 620 nm or greater and 660 nm or less in an emission spectrum.

15. A light-emitting device comprising: a first light emitter; and a second light emitter configured to emit visible light by irradiation with light from the first light emitter;
wherein
the second light emitter includes the phosphor described in claim 2.

16. The light-emitting device according to claim 15, wherein the second light emitter further includes a yellow phosphor and/or a green phosphor.

17. The light-emitting device according to claim 16, wherein the yellow phosphor and/or the green phosphor includes one or more selected from the group consisting of a garnet-based phosphor, a silicate-based phosphor, a nitride phosphor, and an oxynitride phosphor.

18. A lighting device comprising the light-emitting device described in claim 15 as a light source.

19. An image display device comprising the light-emitting device described in claim 15 as a light source.

20. A vehicle indicator lamp comprising the light-emitting device described in claim 15 as a light source.
